(19) United States
(12) Patent Application Publication
(10) Pub. No.: US 2007/0166916 A1
(43) Pub. Date: Jul. 19, 2007

(54) Nanostructures-based optoelectronics device

(75) Inventors: Glenn S. Solomon, Redwood City, CA (US); David J. Miller, San Francisco, CA (US); James D. Heerwagen, Los Gatos, CA (US)

Correspondence Address: Rodney T. Hodgson, Ph.D., 822 Pinesbridge Rd., Ossining, NY, 10562, US

(73) Assignee: Sunvolt Nanosystems, Inc., Redwood City, CA (US)

(21) Appl. No.: 11/331,788

(22) Filed: Jan. 14, 2006

(51) Int. Cl. H01L 21/336

(52) U.S. Cl. 438/257

(57) ABSTRACT

A materials structure is presented which is based on the insertion of preformed nanocrystals of arbitrary shape on or into a non-crystalline, non-hydrocarbon barrier layer. Embodiments of the structure include a variety of barrier layers and contacts, which can be layered. When the structure is used as a detector or a solar cell, transport of charged carriers created in the nanocrystals during the absorption process occurs through quantum mechanical tunneling, thermionic emission or diffusion to electronic contacts. One embodiment of such a structure is a photovoltaic device, where a built-in bias is established using different contact materials and barrier layers. The structure can also be used as a modulator or emitter. The invention may consist of many structures stacked and sharing adjacent contact regions, where individual layers are tuned to absorb, emit or modulate light at a specific frequency or groups of frequencies.

### FIELD OF THE INVENTION

The present invention is in the field of optoelectronics. More specifically, the invention provides devices such as a photovoltaic solar cell, based on the incorporation of inorganic-based nanostructures into the active region, where the single crystal nanostructures are prefabricated and deposited into an inorganic-based amorphous host material. In one embodiment, a quantum mechanical tunneling process moves charged carriers between the nanostructure and surrounding layers.

### BACKGROUND OF THE INVENTION

Optoelectronic devices are typically composed of single crystal active regions of inorganic semiconductors. For example, III-V compounds such as GaAs and GaN compounds like AlGaAs, InAlGaAs, and InGaNP are used both to generate light and as light detectors, while materials such as silicon are used as light detectors and as solar energy converters, Because of the single crystal nature of the active region the surrounding regions must also be single crystal, necessitating a latticed matched set of materials including a latticed matched single crystal substrate. This process is both costly and restrictive. It is costly because of the single crystal, latticed matched substrate and specifically designed and built crystal growth apparatus. It is restrictive because material combinations must be chosen that are optimized for the specific device, and in addition are lattice matched. In particular, the photovoltaic solar cell is an optoelectronic device that converts sunlight to electric power. It is typically formed in a way that is similar to many optoelectronic devices. Thin layers of single crystal, polycrystalline, or amorphous material are deposited on a substrate. A built-in voltage potential is typically made using a junction between n and p doped regions. Sunlight illuminated onto the structures is absorbed creating electrons and holes. The charged carriers diffuse through the structure to electrical contacts and provide a current to an external load impedance. These devices have efficiencies that are related to the materials used and importantly to the crystalline nature of the materials. Average prior art efficiencies are in the 6% range for amorphous silicon (Si) based devices, 15% for polycrystalline Si devices, 25% for single crystal Si devices, and over 30% for multijunction (cascade) AlGaAs—GaAs—Ge devices. Unfortunately, with increased efficiency comes increased manufacturing costs, and it is difficult for this electric power-generating device to compete with other power generation sources.

### OBJECTS OF THE INVENTION

It is an object of the invention to produce an inexpensive optoelectronic device.

It is an object of the invention to produce an inexpensive solar energy conversion device.

It is an object of the invention to produce an inexpensive light emitting device.

### SUMMARY OF THE INVENTION

Preformed nanocrystals are contacted with a noncrystalline, non-hydrocarbon barrier material for use as light detectors, light emitters, and energy conversion devices.

### BRIEF DESCRIPTION OF THE DRAWINGS

FIG. 1 shows a sketch of the start of construction of the apparatus of the invention.

FIG. 2 shows a sketch of a step of construction after the steps of FIG. 1.

FIG. 3 shows a sketch shows a sketch of the most preferred apparatus of the invention.

FIG. 4 shows a sketch of a preferred apparatus of the invention.

FIG. 5 shows a sketch of a preferred apparatus of the invention.

FIG. 6 shows a sketch of a preferred apparatus of the invention.

FIG. 7 shows a sketch of a band diagram of the most preferred apparatus of the invention, wherein no light is incident on the nanocrystals.

FIG. 8 shows a sketch of a band diagram of the most preferred apparatus of the invention, wherein light is incident on the nanocrystals.

FIG. 9 shows a sketch of a band diagram of a preferred apparatus of the invention.

FIG. 10 shows a sketch of a band diagram of a preferred apparatus of the invention.

FIG. 11 shows a sketch of a band diagram of a preferred apparatus of the invention.

### DETAILED DESCRIPTION OF THE INVENTION

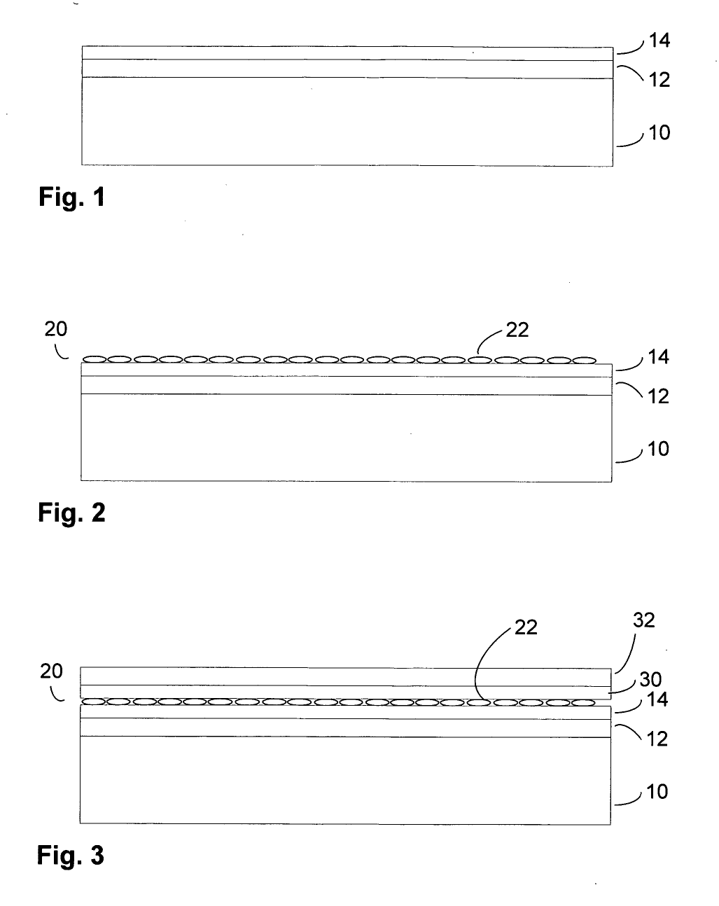

FIG. 1 shows the beginning of a construction process for the apparatus of the invention. A substrate 10 has an optional electrically conducting layer 12 deposited, and on top of the layer 12, a layer of barrier material 14 is deposited. The substrate may be a material transparent to light, such as a glass, a polymeric material, or it may be a non transparent substrate such as stainless steel or any other inexpensive material as is known in the art. If the substrate is an electrically conducting substrate, the electrically conducting layer 12 may be dispensed with. The electrically conducting material of layer 12 may be a material transparent to light such as indium tin oxide (ITO), for some embodiments of the invention, or it may be non-transparent such as a metallic layer of aluminum. The barrier material of layer 14 is a non-crystalline, non hydrocarbon material. For the purposes of this specification, a non-crystalline material is defined as an amorphous material or a material comprising atoms with only very short range ordering, wherein the short range order is over dimensions much less than the largest dimensions of nanocrystals which will be applied to the surface, (shown later). The barrier material of layer 14 may be homogeneous, or it may be a mixture of different material, or it may be a homogenous material with a large percentage of nanoparticles contained therein, where the nanoparticles have dimensions small compared to the largest dimension of the nanocrystals. A hydrocarbon material is defined as a material having a significant number of hydrocarbon (C—H) bonds, where the presence of the hydrocarbon bonds significantly affects the properties of the material. For the purpose of this specification, hydrocarbon material having C—H bonds substituted with C—F, C—Cl, C—Br, and C—I bonds is defined as a hydrocarbon material.

Layer 14 may be deposited on layer 12 by evaporation, sputtering, spin coating, or any other method as known in the art of depositing thin layers. FIG. 2 shows the apparatus of FIG. 1 having a layer 20 of preformed nanocrystals 22 deposited on layer 14. For the purposes of this specification, a nanocrystal is formed of a crystalline material, wherein the atoms of the crystalline material have a long range order of the physical dimensions of the nanocrystal. The maximum dimension of the nanocrystals for the purposes of this specification is defined as 300 nm. The nanocrystals may have spherical, elliptical, or irregular shapes, where all spatial dimensions are comparable, or may be plate shaped, where one spatial dimension is much less than the other two, or rod shaped, where one spatial dimension is much longer than the other two.

FIG. 2 shows many nanocrystals covering layer 14 more or less uniformly, but in some preferred embodiments of the invention, one or a few nanocrystals in a group may be necessary. In the most preferred embodiments of the invention, a large plurality of nanocrystals is required. A large plurality is defined as more than 10,000, and in the most preferred embodiments of the invention the layer 14 is entirely covered with at least one layer of nanocrystals, wherein the substrate 10 has dimensions of cm or meters. The nanoparticles may be applied by themselves to the surface of layer 14, as shown in FIG. 2, or they may be admixed with another material and applied to the surface of layer 14, or layer 14 and layer 20 may be co-deposited on layer 12. The material admixed with the nanocrystals may be the same as the material of layer 12, or another barrier material. The nanocrystals are preferably nanocrystalline for of a semiconductor, most preferably a III-V semiconductor such as GaAs, AlGaAs, GaInAlAs, GaN, a II-Vi material, or an elemental semiconductor. A barrier material is defined as a material wherein a potential energy barrier exists against transferring carriers of at least one type between the conductor material and the preformed inorganic nanocrystals of layer 20. Preferred barrier materials are oxides and nitrides, particularly of silicon. Oxides of other metals such as titanium, scandium, ruthenium etc. are also anticipated for their qualities of chemical stability. Nano particles of these materials admixed into other barrier materials are also anticipated.

FIG. 3 shows two additional layers 30 and 32 deposited on top of the nanocrystal layer. Layer 30 is a barrier layer which may be the same material as layer 14 or a different barrier material. Layer 32 is an electrically conducting layer, which may or may not be a transparent material. If the substrate material and layer 12 are transparent, layer 32 may be a metallic material such as aluminum, which will serve as both an electrical conductor and as a hermetic seal.

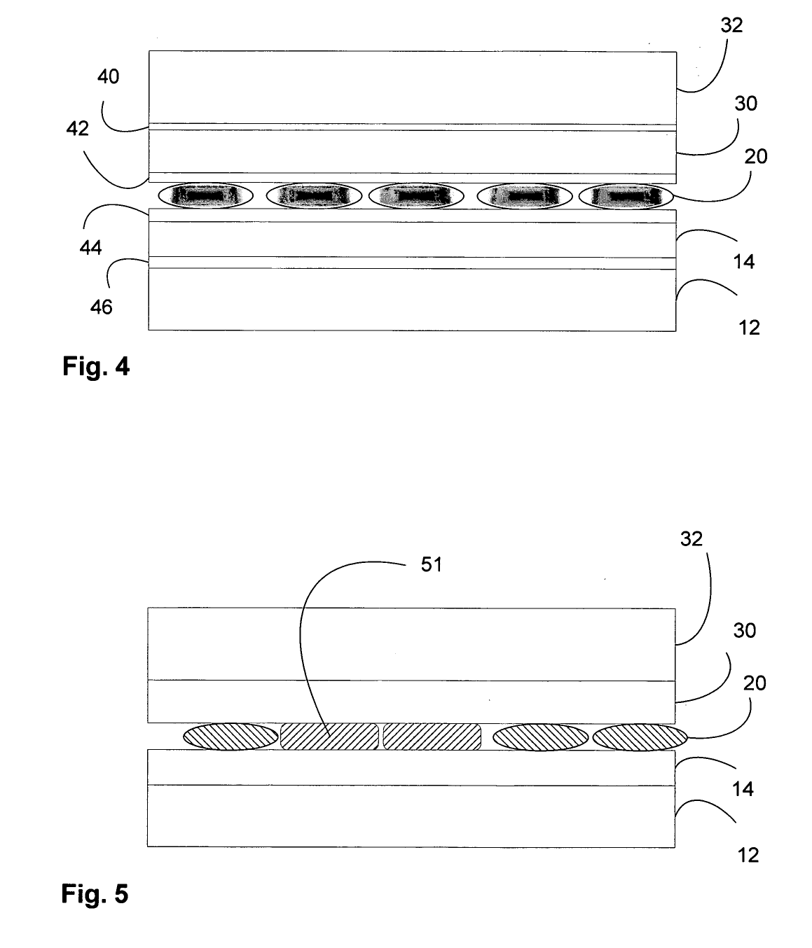

FIG. 4 is an enlarged view of the apparatus of the invention, wherein optional additional layers of material 40, 42, 44, and 46 are introduced for various purposes such as passivation layers and diffusion barrier layers.

The structure of FIG. 3 shows the electrically conducting layers 12 and 32 in physical contact with barrier layers 14 and 34, which are in physical contact with the nanocrystals of layer 20. In the present invention, physical contact between these layers is not required, as long as electrical contact is maintained. Electrical contact is maintained when the electrical potentials of the various layers are determined, at least in part, by the potentials of another layer. For example, a current may flow between two electrically contacted materials separated by a layer of another material, or the potential of one layer is affected by capacitive coupling from the other, or charge carriers may travel from one layer to the next by diffusion, by tunneling, by field or thermionic emission, or by other means as known in the art or any combination of such means. The most preferred charge carrier movement is by tunneling. A preferred method of transfer of carriers is by a combination field emission of electrons and diffusion of holes.

FIG. 5 shows a sketch of the layer 20 formed from nanocrystals 51 of different shape or different materials.

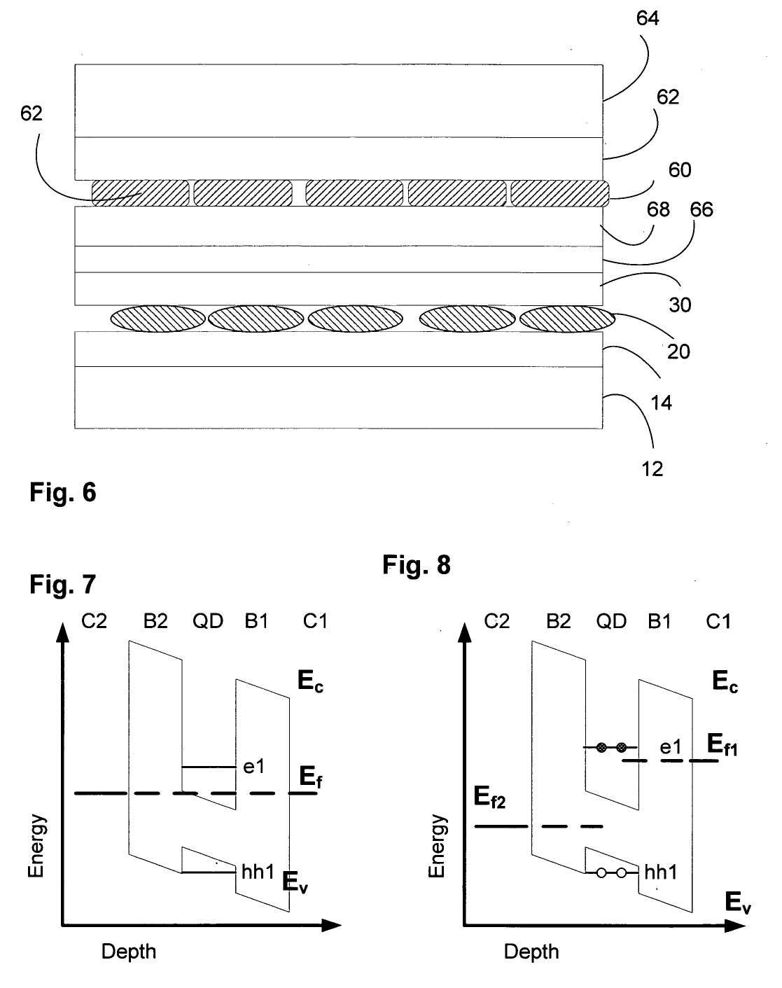

FIG. 6 shows that the invention of FIG. 2 can be stacked one on top of the other. Conducting layers 64 and 66, barrier layers 62 and 68, and a layer 60 of nanocrystals 62 are deposited on a previously formed device. In FIG. 6, layers 66 and 68 are optional, as layer 30 will serve as a barrier layer for both nanocrystal layers 20 and 60.

FIG. 7 shows a schematic band diagram for the most preferred apparatus of the invention of FIG. 3 without solar illumination. The dashed line represents the Fermi level (Ef). Component layers include the nanocrystal or quantum dot (QD) layer 20, two barrier layers (B1,B2) representing layers 14 and 30, and two contact layers (C1,C2) representing layers 12 and 32. The and Barrier Conduction (Ec) and Valence (Ev) bands are tilted because of the different work functions of the conductors, where the work function is defined as the distance between the vacuum level (E_{vac}) and Ef. E′_{vac} represents the vacuum level before the contact, C2 is mated with the rest of the structure. The difference in work functions is responsible for the slope of Ec and Ev.

The Fermi level of a system is defined in equilibrium; it is a constant energy level throughout the system and is defined as the energy at which the probability of electron occupation is ½. The work function, defined as the difference between the Fermi level and the vacuum level is typically different for different materials. Here, we initially design the work function of the two contacts to be different, thus sloping the conduction band (Ec) and valence band (Ev). This creates an important difference in the height of Ec on each side of the QD conduction state with respect to this state.

A unique feature of one embodiment of this device is the tunneling nature of the transport. If the charge carriers generated at the QD where transported by diffusion through the amorphous layers, the minority carrier diffusion length would likely be short; the transport properties would not be optimum as in an amorphous Si device. However, if the charged carriers quantum mechanically tunnel through the barrier, the mean diffusion length does not matter, except for issues related to barrier defects. If the energy difference between QD valence and conduction states are equal to the energy of photons illuminated on it, and the valence state is filled, while the conduction state is empty, then there is a probability that the photon will be absorbed by the QD, and an electron from the filled valence state can be excited to the conduction state, leaving a hole. This electron can relax back to the valence state and recombine with the hole in a characteristic time called the spontaneous emission radiative lifetime, or relax nonradiatively through defects or phonons with a nonradiative lifetime. However, in our device the electron tunnels through the barrier region and into the conductor, before any of the above processes occur. In parallel, the hole created in the QD valence state tunnels in the opposite direction, through a different barrier layer and into the other contact. Thus, the characteristic tunneling time must be shorter than the radiative and nonradiative lifetimes. Because the heights of Ec and Ev are different on each side of the QD, electrons preferentially tunnel through B1 to C1, while holes preferentially tunnel through B2 to C2.

In this simple equilibrium picture above, with minimum illumination and no load, carriers will tunnel back and forth from C1 (C2) through B1 (B2) into the QD. However, under proper illumination and loading, electrons will build up negative charge on one side while holes build up positive charge on the other side, the system will not be in equilibrium and thus cannot be represented by a single Fermi level. The Fermi level on the C1 side will rise (becoming more negative), while the Fermi level on the C2 side will fall. This is represented in FIG. 8.

The tunneling current is initially dependent on an exponential function of the barrier height and width. Thus, small differences in a function related to the barrier height and width will lead to large differences in tunneling current. Two processes will bring the tunneling current back into equilibrium and clamp the voltage. First, as the injected carrier flux into the contacts increases the difference in quasi Fermi levels continue to increase. When the quasi Fermi levels reach the QD levels the current into and out of the QD states equilibrates. Alternatively, as the quasi Fermi level differences increase with increasing current, the electric field becomes more compensated, the barrier bands become more flattened and therefore the tunneling current reduces. Which one of these processes dominates depends on the amount of band tilting (the difference in work functions of the two contacts) versus the difference in the QD states and the quasi Fermi levels. If the band tilting processes limit the voltages, it will produce a slow reduction in current with increased voltage as the reverse tunneling current increases. However, if the alignment of the quasi Fermi level with the QD confined states controls the current from the QD absorption, it will lead to a steep reduction in current as the critical voltage is reached. The later process, limited by the quasi Fermi level alignment with the QD will ultimately give the largest I*V product (power), an important design parameter. Finally, the hole and electron tunneling currents are dependent. In an ideal QD structure they must be the same, since absorption cannot take place if the valence state is empty (hole occupation),and absorption cannot take place if there is already an electron in the conduction state. Both the hole and electron must tunnel to the contacts before the system can be returned to its initial state. Even if the absorption takes place in a quantum wire or well, with a band of states instead of the discrete QD states, the tunneling of electrons and holes will come to equilibrium through the circuit. It is not necessary and the device may not be optimized for the tunneling of both electrons and holes. Typically, the hole state is more weakly confined than the electron state (as in FIG. 8). Carrier transport from this state maybe from diffusion over the top of the barrier, weakly confined tunneling, or some combination of both processes. While not common, it could be that the above process occurs in the conduction states, or both—it can be used as a design parameter.

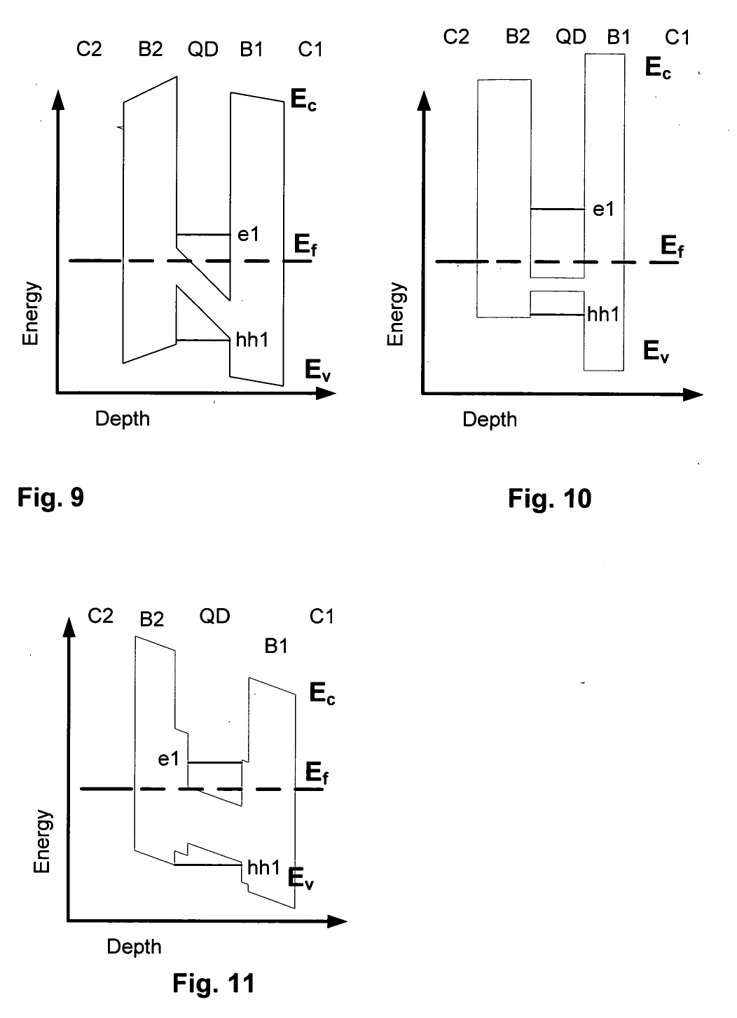

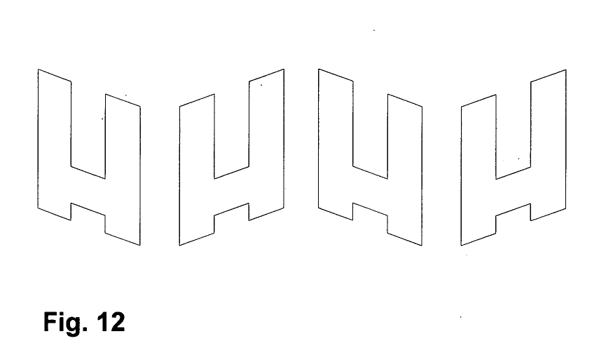

There are a few ways to improve on the initial device and force the voltage to be limited by the increase in quasi Fermi levels instead to the band tilt flattening. The co-tunneling in the parasitic (opposite) directions needs to be minimized. An increase in one of the barrier widths to limit tunneling of one of the carriers will produce the necessary preferential tunneling, but this must be done in such a way that it does not reduced the other carrier type (electron or hole) from tunneling in that direction. For example, FIG. 9 shows that if the width of B2 in FIG. 7 increases it reduces electron tunneling in that direction even when the tilt is removed. However, it will does not diminish the hole tunneling substantially because the hole state is weakly confined. If the hole state was not designed this way initially, the hole tunneling would be reduced. Another approach is to make the work functions of barrier B1 and B2 different as depicted in FIG. 10 so that the barrier height to electrons of say B2 increases and at the same time diminishes the hole barrier height of B2.

In FIG. 9, the barrier widths are different and one barrier has a unique work function with respect to the other materials. In FIG. 10, the work functions are all the same but the barrier widths and heights are different.

Optimizing the photovoltaic solar cell involves many design aspects, but we focus on only two here: (i) Optimization of sunlight absorption; and (ii) Optimization of the power derived from that absorption. Optimization of solar absorption is the optimization of the absorption of photons with a particular energy distribution. Terrestrial solar incidence is governed by the normal radiative distribution of a thermal body modified by atmospheric absorption. The resulting distribution is naturally broken into three or four regions. Ideally, we will choose nanocrystals that, when placed between barriers, have absorption regions centered on these regions. There is likely a design choice here as the ground-state absorption is governed by the general material of the nanocrystal, the size of the nanocrystal, and also to some extend the barrier height surround the nanocrystal in the solar cell. We do not seek necessarily narrow nanocrystal size distributions because we want the nanocrystal absorption distribution to cover regions of the terrestrial solar spectrum. There are clear peaks in the photon flux versus photon energy curve of sunlight reaching the earth's surface. From this data we know that most of the photons on the earth's surface coming from the sun have an energy of approximately 750 meV. This energy corresponds to a wavelength of 1.65 μm. The spectral range of photons contributing the most energy to the system is near 500 nm, corresponding to 2.5 eV. The next largest contribution is from the wavelength region centered on 626 nm, corresponding to 2 eV. Since we are interested in obtaining large energy conversion, not photon conversion, we should design our system to capture 2.5 eV and 2 eV photons, and to a lesser extent 3.3 eV, 1.67 and 1.45 eV photons. Since the photon flux at 1.45 eV is about twice as at 2.5 eV we must add more nanocrystals at these lower energies, even though the energy output will be lower.

Optimization of the power derived from solar absorption is also related to the solar cell material choices. Specifically, the work functions of the contact and barrier materials, and the position of the confined nanocrystal states will have a strong effect on the device performance. There is a large parameter space for materials choices. From the last section, in the simple solar cell example, the work function difference of the two contact layers is critical both to the initial tunneling process establishing a current direction, and to the total voltage that can be achieved. However, the same effect can be achieved by tuning the thickness of the two barriers and either picking an advantageous nanocrystal work function for one of the barriers, or having the one of the barriers be a different height (in energy) than the other.

Materials Issues Related to Manufacturing

A critically important aspect of this solar cell is the development of a high-throughput, low-cost manufacturing process. An example would be the sputtering of layers onto a glass or thin metal substrate. However, all materials cannot be sputtered, and more specifically all materials cannot be properly sputtered at relatively low temperatures, and even more specifically all materials do not deposit well together through sputtering. Chemical reactions between layers, defects at the junctions between layers and point defects within layers must all be considered. It is likely that if we want to reduced interface and point defect states, elevated temperatures are desirable. The temperature is clamped by two issues. One is the colloidal nanocrystal material, which are often made from group II-VI compound semiconductors. These materials can generally withstand temperatures up to 400° C. without degradation. Additionally, for high-throughput, low-cost processing elevated temperatures are in general not desirable. The device calls for a highly specific set of energy band offsets, which will likely constrain our materials choices. Chemical issues will certainly also play roles. For example, while the nearly perfect silicon-silcon dioxide interface has been one of the foundations of the microelectronics industry, most interfaces either react or have higher surface state densities. An issue that will clearly be important is the spraying of the nanocrystal material. The nanocrystal material may be stored in a solvent. It is unlikely that the solvent will be compatible with the other materials and so it must be removed before deposition. In addition, there are issues with the deposition of the nanocrystals onto the barrier layer. If then nanocrystal density is too large, clumping of the nanocrystals will occur and diminish the device characteristics: the nanocrystals will no longer be isolated in a large bandgap material. This clumping could also occur through the deposition process if the nanocrystals do not contain the proper surface coating to reduce aggregation. Sputtering is a line-of-sight process. Thus, the nanocrystals will shadow the region directly below the nanocrystals, leading to voids. These macroscopic voids occur because the nanocrystals sit firmly on top of the barrier region, while it would be desirable if the the Nanocrystals were embedded within the region. An intermediate layer could be inserted to serve this function. This is illustrated in Fig. A separate issue is microscale defects that may result between the nanocrystals and the surrounding regions. Such defects include point defects, microvoids, and poor or incorrect bonding. As with the shadowing issue, it may be desirable to insert a passivating layer around the nanocrystals to insure proper surface passivation. While the passivating layer will ideally surround the nanocrystals and provide a pristine interface, it will not necessarily reduce shadowing. Thus, two sets of interlayers may be necessary, one to reduce shadowing and one to aid in passivation.

Multi-layer PV Cell Layers

So far we have discussed only a single layer of nanocrystals and its associated barriers and contacts. We need many layers both of redundant nanocrystal absorption to increase the wavelength specific absorption, and different nanocrystals absorbing in different spectral regions to adequately cover the solar spectrum. These layers may be simply connected by flipping layers so that on adjacent layers holes and electrons are traveling in opposite directions, sharing contacts. A band diagram outlining such a scheme is shown in FIG. 12. While simple in concept, an extra processing step must occur to join all the even and odd contact layers. Furthermore, we must determine if all the nanocrystal states in the group need to absorb at the same wavelength. It is likely that Vsc will clamp at the lowest nanocrystal energy. Thus, if different color absorbing layers are joined together some power conversion will be sacrificed. However, if the different color absorbing nanocrystal layers are separated an elaborate contacting scheme must be used.

In addition to use of the apparatus as a solar cell, the invention provides several other electronic devices that absorb light, including a detector. Also provided are devices that emit and modulate light.

Obviously, many modifications and variations of the present invention are possible in light of the above teachings. It is therefore to be understood that, within the scope of the appended claims, the invention may be practiced otherwise than as specifically described.

We claim:

1. An apparatus, comprising:
a large plurality of preformed inorganic nanocrystals;
at least one non-hydrocarbon, non-crystalline barrier material, wherein the large plurality of preformed inorganic nanocrystals are in electrical contact with the non-crystalline, non-hydrocarbon barrier material, and wherein a potential energy barrier exists against transferring carriers of at least one type between the non-crystalline, non-hydrocarbon, barrier material and the large plurality of preformed inorganic nanocrystals;
and, at least one electrically conducting material in electrical contact with the barrier material.

2. The apparatus of claim 1, wherein the large plurality of preformed inorganic nanocrystals are formed in a first layer on top of and in electrical contact with a second layer of a first non-hydrocarbon, non-crystalline barrier material, and wherein the second layer is on top of and in electrical contact with a third layer of a first electrically conducting material.

3. The apparatus of claim 2, wherein a fourth layer of a second non-hydrocarbon, non-crystalline barrier material is formed on top of and in electrical contact with the first layer of the large plurality of preformed inorganic nanocrystals.

4. The apparatus of claim 3, wherein a fifth layer of a second electrically conducting material is formed on top of the fourth layer, wherein the fifth layer is in electrical contact with the fourth layer.

5. The apparatus of claim 4, wherein at least one of the third and a fifth layer of electrically conducting material is transparent to at least one frequency of electromagnetic radiation, wherein the at least one frequency is in the ultraviolet to the infra-red region.

6. The apparatus of claim 5, wherein the nanocrystal layer absorbs light centered on at least one wavelength.

7. The apparatus of claim 6, wherein the at least one frequency of electromagnetic radiation passes through the transparent conducting material and is absorbed in the preformed inorganic nanocrystals to produce an electrical current flow between the third and the fifth layers.

8. The apparatus of claim 7, wherein the direction of the electrical current flow between the third and the fifth layers determined by a built-in potential formed by electrical contact regions of different work functions.

9. The apparatus of claim 7, wherein the direction of the electrical current flow between the third and the fifth layers determined by a built-in potential formed by different electron affinities of the materials of the second and fourth layers.

10. The apparatus of claim 7, wherein the nanocrystal layer is a compound layer formed by layers of nanocrystals separated by non-crystalline, non-hydrocarbon, barrier materials.

11. The apparatus of claim 6, wherein a distribution of absorbed wavelengths is determined by at least one of the size, shape and material of the nanocrystals.

12. The apparatus of claim 4, wherein at least one additional layer of material is present between at least one of the pairs comprising the second and third layers and the fourth and fifth layers, wherein the additional layer of material facilitates electrical contact between the layers.

13. The apparatus of claim 1, wherein the non-hydrocarbon, non-crystalline barrier material comprises a plurality of layers of different compositions.

14. The apparatus of claim 5, wherein carriers transported to the large plurality of inorganic nanocrystals recombine and produce electromagnetic radiation.

15. The apparatus of claim 1, wherein the non-hydrocarbon, non-crystalline barrier material comprises nitride or oxide containing compounds.

16. The apparatus of claim 1, wherein the nanocrystals comprise semiconductor material.

17. The apparatus of claim 1, wherein at least one electrically conducting transparent material comprises indium tin oxide.

18. The apparatus of claim 1, wherein one or more layers of material is interposed between the non-hydrocarbon, non-crystalline barrier material and the nanocrystal, wherein the one or more layers of material facilitates electrical contact between the non-hydrocarbon, non-crystalline barrier material and the nanocrystal.

20. An apparatus, comprising:
at least one preformed inorganic nanocrystal;
at least one non-hydrocarbon, non-crystalline barrier material, wherein the at least one preformed inorganic nanocrystal is in electrical contact with the non-crystalline, non-hydrocarbon barrier material, and wherein a potential energy barrier exists against transferring carriers of at least one type between the non-crystalline, non-hydrocarbon, barrier material and the at least one preformed inorganic nanocrystal.

21. The apparatus of claim 20, wherein the at least one preformed inorganic nanocrystal is derived from a colloidal solution of nanocrystals.

22. The apparatus of claim 20, wherein the at least one preformed inorganic nanocrystal shape is chosen from the group consisting of spherical, oval, rod, wire, and plate shapes.

23. The apparatus of claim 20, wherein energy states of the at least one preformed inorganic nanocrystal are determined in part by quantum confinement in at least one dimension.

24. The apparatus of claim 20, wherein electromagnetic radiation incident on the at least one inorganic nanocrystals is absorbed to produce electrical current.

25. The apparatus of claim 24, wherein the apparatus is a solar cell.

26. The apparatus of claim 20, wherein electromagnetic radiation incident on the at least one inorganic nanocrystals is absorbed to produce a light modulator.

27. The apparatus of claim 20, wherein carriers transported to the at least one inorganic nanocrystal recombine to produce electromagnetic radiation.

28. The apparatus of claim 20, wherein carriers transported through the non-hydrocarbon, non-crystalline barrier material are transported at least partially by quantum tunneling.

29. The apparatus of claim 20, wherein carriers transported through the non-hydrocarbon, non-crystalline barrier material are transported at least partially by thermionic emission.

30. The apparatus of claim 20, wherein carriers transported through the non-hydrocarbon, non-crystalline barrier material are transported at least partially by diffusion.

31. The apparatus of claim 20, wherein the at least one nanocrystal is a semiconductor material crystal.

32. The apparatus of claim 31, wherein the semiconductor material is a III-V semiconductor.

33. An apparatus, comprising:
a substrate;
a first layer of a first electrically conducting material formed on the substrate;
a second layer comprising a first non-hydrocarbon, non-crystalline barrier material formed on the first layer;
a third layer comprising large plurality of preformed inorganic nanocrystals formed on the second layer;
a fourth layer comprising second non-hydrocarbon, non-crystalline barrier material formed on the third layer; and
a fifth layer of a second electrically conducting material formed on the fourth layer;
wherein a potential energy barrier exists against transferring carriers between the barrier materials and the nanocrystals.

34. The apparatus of claim 33, wherein at least one of the first and a fifth layers is transparent to at least one frequency of electromagnetic radiation, wherein the at least one frequency is in the ultraviolet to the infra-red region.

35. The apparatus of claim 34, wherein carriers transported to the large plurality of inorganic nanocrystals recombine and produce electromagnetic radiation of the at least one frequency.

36. The apparatus of claim 34, wherein electromagnetic radiation is absorbed in the large plurality of preformed inorganic nanocrystals to produce a current between the first and the fifth layer.
